(19) United States
(12) Patent Application Publication
(10) Pub. No.: US 2009/0090919 A1
(43) Pub. Date: Apr. 9, 2009

(54) Semiconductor device and method of producing the same

(75) Inventor: Hidetsugu Uchida, Tokyo (JP)

Correspondence Address: KUBOTERA & ASSOCIATES, LLC, Suite 202, 200 Daingerfield Road, Alexandria, VA, 22314, US

(73) Assignee: Oki Electric Industry Co., Ltd.

(21) Appl. No.: 12/230,774

(22) Filed: Sep. 4, 2008

(30) Foreign Application Priority Data
Oct. 3, 2007 (JP) 2007-259700

(51) Int. Cl. H01L 21/28; H01L 29/24

(52) U.S. Cl. 257/77; 438/585; 257/E29.104; 257/E21.19

(57) ABSTRACT

A semiconductor device includes a silicon carbide substrate having a channel region formed on a surface thereof; a silicon layer formed on the channel region; a gate insulation film formed on the silicon layer; and a gate electrode formed on the gate insulation film. A method of producing a semiconductor device includes the steps of: forming a silicon layer on a surface of a silicon carbide substrate; forming a gate insulation film on the silicon layer to form a laminated structure of the silicon layer and the gate insulation film; and forming a gate electrode on the gate insulation film.

### BACKGROUND OF THE INVENTION AND RELATED ART STATEMENT

The present invention relates to a semiconductor device. More specifically, the present invention relates to a semiconductor device such as a high voltage MOSFET (Metal Oxide Semiconductor Field Effect Transistor) using a silicon carbide substrate (an SiC substrate). The present invention also relates to a method of producing the semiconductor device. More specifically, the present invention relates to a method of producing the semiconductor device related to a technology of forming a gate insulation film.

Conventionally, a wide band gap semiconductor has been known for an element of a semiconductor device, in which it is possible to obtain a high breakdown voltage and flow a large current. Among the wide band gap semiconductors, silicon carbide (SiC) has been known to have an especially high breakdown voltage. Further, it is possible to form a silicon dioxide film (an SiO₂ film) with excellent property on silicon carbide through thermal oxidation.

As disclosed in Patent References 1 to 3, an SiC power device of an insulation gate type has been developed. In the SiC power device, a silicon dioxide film (an SiO₂ film) is used as a gate insulation film. In the SiC power device, there are adopted a large number of elements with a gate insulation film such as a DiMOSFET (Double Implanted MOSFET), an MOSFET, an MOS capacitor, and the likes.

Patent Reference 1: Japanese Patent Publication No. 60-66866

Patent Reference 2: Japanese Patent Publication No. 08-51110

Patent Reference 3: Japanese Patent Publication No. 2006

FIG. 8 is a schematic sectional view showing a conventional semiconductor device disclosed in Patent Reference 3. The conventional semiconductor device is a DiMOSFET of a vertical type formed using an SiC wafer.

As shown in FIG. 8, the conventional semiconductor device includes an SiC substrate 1 of an N+ type. An epitaxial layer 2 of an N− type as a drift layer is formed on a front surface of the SiC substrate 1. A plurality of well regions 3 of a P-type is formed on a front surface of the epitaxial layer 2 with a specific space in between.

Further, a source region 4 of an N+ type is formed inside each of the well regions 3. A source region 5 of a P+ type for contacting is formed in each of the source regions 4. A channel region is formed between the well regions 3, and a gate insulation film 6 formed of an SiO₂ film is formed on the channel region. A gate electrode 7 is formed on the gate insulation film 6.

An interlayer insulation film 8 formed of an SiO₂ film covers a whole surface including the gate electrode 7. A part of the interlayer insulation film 8 is opened, so that the source region 5 and a part of the source regions 4 are exposed. A source electrode 9 is formed and electrically connected to the source regions 4 and 5 thus exposed. A wiring portion 10 is selectively formed on the interlayer insulation film 8, so that the wiring portion 10 is electrically connected to the gate electrode 7 and the source electrode 9. A drain electrode 11 is formed on a backside surface of the SiC substrate 1.

In general, in the DiMOSFET of this type, it is necessary to provide a switching property, in which a large current flows from the drain electrode 11 to the source electrode 9 with a minimum loss when power is turned on, and no current flows even upon applying a voltage of few hundreds volt when power is turned off.

In an operation of the DiMOSFET, when power is turned on, a positive voltage is applied to the gate electrode 7. Accordingly, a channel is formed below the gate electrode 7 and a resistivity decreases, thereby obtaining an on state electrically. When power is turned off, zero voltage is applied to the gate electrode 7. Accordingly, no channel is formed below the gate electrode 7 and the resistivity decreases, thereby obtaining an off state electrically.

As described above, in the operation of the DiMOSFET, a high voltage is applied to the gate insulation film 6. Accordingly, it is necessary to provide the gate insulation film 6 with an excellent high voltage insulation property and reliability. The requirement is applicable to not only the DiMOSFET but also other SiC devices such as an MOSFET and an MOS capacitor using a gate insulation film.

In a conventional method of forming the gate insulation film 6 on the SiC substrate 1, the SiC substrate 1 is directly subject to thermal oxidation. As opposed to an Si substrate, it is difficult to form the gate insulation film 6 with a high voltage and good reliability on the SiC substrate 1. Further, the gate insulation film 6 tends to have a high fixed charge concentration, so that carbon in the SiC substrate diffuses into the gate insulation film 6, thereby causing a variance in a threshold voltage of the transistor.

Further, an interface between the gate insulation film 6 and the SiC substrate 1 tends to have a high interface trap density, thereby lowering channel mobility of the transistor (channel conductance) or varying the threshold voltage thereof. Accordingly, it is difficult to easily produce the semiconductor device such as the DiMOPSFET with a high voltage and good reliability.

In view of the problems described above, an object of the present invention is to provide a semiconductor device and a method of producing the semiconductor device capable of solving the problems of the conventional semiconductor device and the conventional method of producing the semiconductor device.

Further objects and advantages of the invention will be apparent from the following description of the invention.

### SUMMARY OF THE INVENTION

In order to attain the objects described above, according to a first aspect of the present invention, a semiconductor device includes a silicon carbide substrate having a channel region formed on a surface thereof; a silicon layer formed on the channel region; a gate insulation film formed on the silicon layer; and a gate electrode formed on the gate insulation film.

According to a second aspect of the present invention, a method of producing a semiconductor device includes the steps of: forming a silicon layer on a channel region on a surface of a silicon carbide substrate; forming a gate insulation film on the silicon layer to form a laminated structure of the silicon layer and the gate insulation film; and forming a gate electrode on the gate insulation film.

In the present invention, the silicon layer is formed on the surface of the silicon carbide substrate. Accordingly, the gate insulation film does not directly contact with the silicon carbide substrate. As a result, it is possible to prevent carbon in the silicon carbide substrate from migrating into the gate insulation film. Therefore, it is possible to prevent an insulation voltage and reliability of the gate insulation film from lowering, and to suppress an increase in a fixed charge amount in the gate insulation film.

Further, the interface between the gate insulation film and the silicon layer prevents an interface trap density from increasing.

### BRIEF DESCRIPTION OF THE DRAWINGS

FIG. 1 is a schematic sectional view showing a configuration of a semiconductor device according to a first embodiment of the present invention;

FIGS. 2(A) and 2(B) are schematic sectional views No. 1 showing a method of producing the semiconductor device according to the first embodiment of the present invention;

FIGS. 3(A) and 3(B) are schematic sectional views No. 2 showing the method of producing the semiconductor device according to the first embodiment of the present invention;

FIG. 4 is a schematic sectional view No. 3 showing the method of producing the semiconductor device according to the first embodiment of the present invention;

FIG. 5 is a schematic sectional view No. 4 showing the method of producing the semiconductor device according to the first embodiment of the present invention;

FIG. 6 is a schematic sectional view No. 5 showing the method of producing the semiconductor device according to the first embodiment of the present invention;

FIGS. 7(A) to 7(C) are schematic sectional views showing a method of producing a semiconductor device according to a second embodiment of the present invention; and

FIG. 8 is a schematic sectional view showing a conventional semiconductor device.

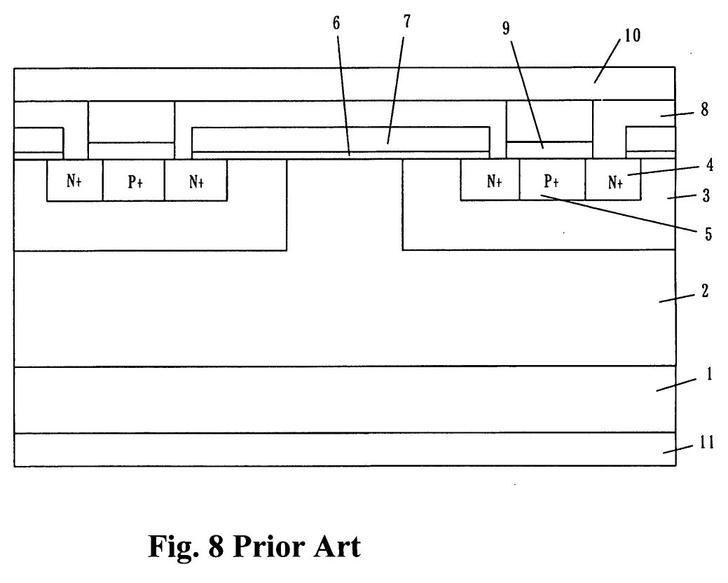

### DETAILED DESCRIPTION OF PREFERRED EMBODIMENTS

Hereunder, preferred embodiments of the present invention will be explained with reference to the accompanying drawings. In the embodiments, a semiconductor device includes a silicon carbide (SiC) substrate having a channel region formed on a surface thereof; a silicon layer formed on the SiC substrate; a gate insulation film formed on the silicon layer; and a gate electrode formed on the gate insulation film.

### First Embodiment

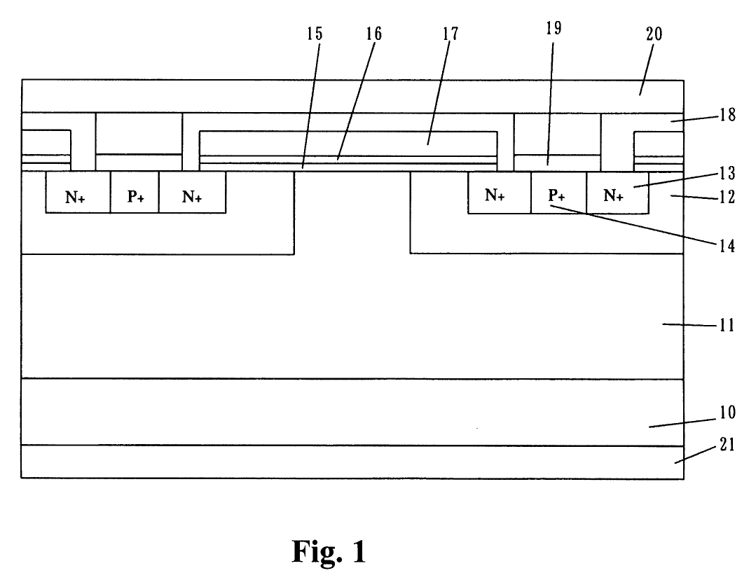

A first embodiment of the present invention will be explained. FIG. 1 is a schematic sectional view showing a configuration of a semiconductor device according to a first embodiment of the present invention.

In the embodiment, the semiconductor device is a DiMOSFET (Double Implanted Metal Oxide Semiconductor Field Effect Transistor) of a vertical type formed using a silicon carbide (SiC) wafer. As shown in FIG. 1, the semiconductor device includes an SiC substrate 10 of an N+ type. An epitaxial layer 11 of an N− type as a drift layer is formed on a front surface of the SiC substrate 10. A plurality of well regions 12 of a P− type is formed on a front surface of the epitaxial layer 11 with a specific space in between.

In the embodiment, a source region 13 of an N+ type is formed inside each of the well regions 12. A source region 14 of a P+ type for contacting is formed in each of the source regions 13.

Different from a conventional semiconductor device, a silicon (Si) layer 15 is formed on a channel region formed between the well regions 12. A gate insulation film 16 formed of an oxidation (SiO₂) film or an oxynitride (SiON) film is formed on the Si layer 15. A gate electrode 17 is selectively formed on the gate insulation film 16.

In the embodiment, an interlayer insulation film 18 formed of an SiO₂ film covers a whole surface including the gate electrode 17. A part of the interlayer insulation film 18 is opened, so that the source regions 14 and a part of the source regions 13 are exposed. A source electrode 19 is formed and electrically connected to each of the source regions 13 and 14 thus exposed. A wiring portion 20 is selectively formed on the interlayer insulation film 18, so that the wiring portion 20 is electrically connected to the gate electrode 17 and the source electrodes 19. A drain electrode 21 is formed on a backside surface of the SiC substrate 10.

As described above, in the embodiment, different from the conventional semiconductor device, the DiMOSFET include a laminated structure of the Si layer 15 and the gate insulation film 16. In the DiMOSFET, similar to the conventional semiconductor device, it is necessary to provide a switching property, in which a large current flows from the drain electrode 21 to the source electrodes 19 with a minimum loss when power is turned on, and no current flows even upon applying a voltage of few hundreds volt when power is turned off.

In an operation of the DiMOSFET, similar to the conventional semiconductor device, when power is turned on, a positive voltage is applied to the gate electrode 17. Accordingly, a channel is formed below the gate electrode 17 and a resistivity decreases, thereby obtaining an on state electrically. When power is turned off, zero voltage is applied to the gate electrode 17. Accordingly, no channel is formed below the gate electrode 17 and the resistivity decreases, thereby obtaining an off state electrically.

As described above, in the embodiment, the DiMOSFET includes the laminated structure of the Si layer 15 and the gate insulation film 16 formed on the SiC substrate 10. Accordingly, the gate insulation film 16 does not directly contact with the SiC substrate 10. As a result, it is possible to prevent carbon in the SiC substrate 10 from migrating into the gate insulation film 16. Therefore, it is possible to prevent an insulation voltage and reliability of the gate insulation film 16 from lowering, and to suppress an increase in a fixed charge amount in the gate insulation film 16.

Further, the interface between the gate insulation film 16 and the Si layer 15 prevents an interface trap density from increasing.

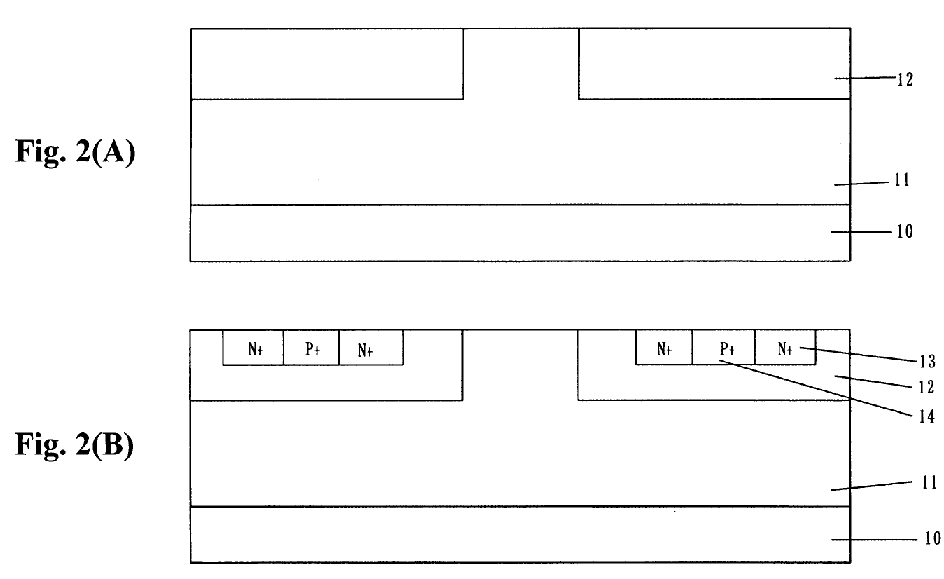

A method of producing the semiconductor device will be explained next. FIGS. 2(A)-2(B) to 6 are schematic sectional views No. 1 to No. 5 showing the method of producing the semiconductor device according to the first embodiment of the present invention.

In the first step, as shown in FIG. 2(A), the epitaxial layer 11 with an impurity ion of an N− type doped therein is formed on the SiC substrate 10 of the N+ type. In forming the epitaxial layer 11, SiC is epitaxially grown with a CVD (Chemical Vapor Deposition) method at a temperature between 1,000° C. and 2,000° C., so that the epitaxial layer 11 has a film thickness of 1 μm to 20 μm.

In the next step, a mask for forming the well regions is disposed on a surface of the epitaxial layer 11. Then, an impurity ion of a P− type such as aluminum (Al) and boron (B) is introduced to form a plurality of the well regions 12. After the well regions 12 are formed, the mask is removed.

In the next step, as shown in FIG. 2(B), a mask for forming the source regions is disposed on the epitaxial layer 11 with the well regions 12 formed thereon. Then, an impurity ion of an N+ type such as phosphorous (P) and nitrogen (N) is introduced to form the source regions 13 of the N+ type. Then, a mask for forming the contact region is disposed on the epitaxial layer 11 with the source regions 13 formed thereon. Then, an impurity ion of a P+ type such as aluminum (Al) and boron (B) is introduced to form the source regions 14 of the P+ type for contacting.

In the next step, the SiC substrate 10 with the source regions 14 of the P+ type formed thereon is placed in a high temperature oven at a temperature of, for example, between 1,000° C. and 2,000° C. under an inert gas environment such as nitrogen gas (N₂) and argon gas (Ar) or under vacuum to perform crystallization annealing, so that the impurity ion thus introduced is activated. Through the process described above, it is possible to obtain a so-called DI (Double Implanted) structure of the well regions 12 and the source regions 13.

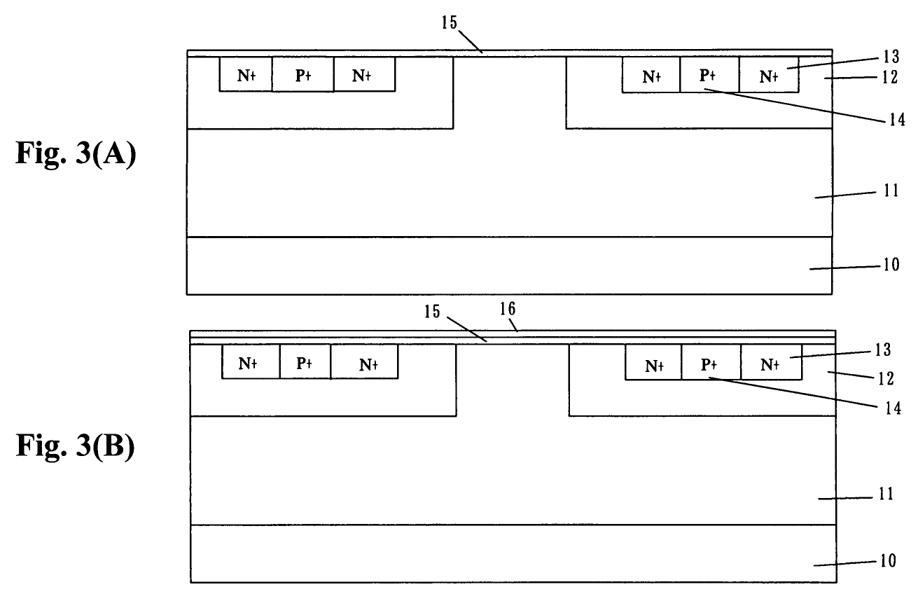

In the next step, as shown in FIG. 3(A), the Si layer 15 having a thickness of, for example, 1 nm to 100 nm is formed on the surface of the epitaxial layer 11 with the source regions 13 and the source regions 14 formed thereon. In forming the Si layer 15, there is used a method such as a deposition method, a low pressure CVD (LPCVD) method, an atmospheric pressure CVD (APCVD) method, a plasma CVD method, sputtering, and the likes. The method is not limited thereto, and any one of the methods may be used.

In an epitaxial growth method, when the SiC substrate 10 has a 3C structure (100), the SiC substrate 10 has a lattice constant similar to that of silicon (100), thereby making the epitaxial growth easy. In the epitaxial growth method, mono-silane (SiH₄) or dichloro-silane (SiH₂Cl₂) may be used as a reaction gas, and the Si layer 15 is deposited at a temperature of, for example, 600° C. to 1,000° C., through the epitaxial growth. In the LPCVD method, the APCVD method, or the plasma CVD method, a silane gas such as SiH₄, SiH₂Cl₂, di-silane (Si₂H₆) is used for depositing the Si layer 15.

In the next step, as shown in FIG. 3(B), using a combination of an oxidation gas such as O₂ and H₂O; a gas containing nitrogen such as N₂O, NO, NO₂, NH₃, N₂, and the likes; and an inter gas such as Ar and the likes, the Si layer 15 is processed through thermal oxynitridation, plasma oxidation, plasma oxynitridation, plasma nitridation, ozone oxidation, anneal process, and the like to form the gate insulation film 16 formed of the oxidation film (SiO₂) or the oxynitride film (SiON). In the step, the Si layer 15 is not completely oxidized or nitrided, so that a part, for example, 0.1 nm to 90 nm, of the Si layer 15 remains.

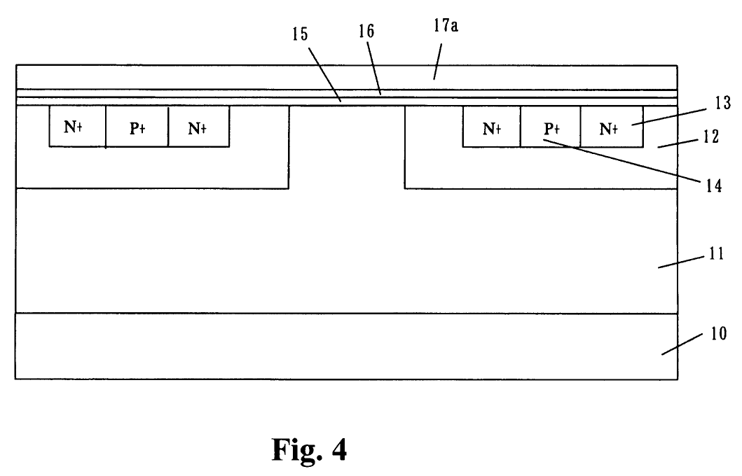

In the next step, as shown in FIG. 4, a ploy-silicon layer 17a is formed on the gate insulation film 16 for forming the gate electrode 17. The poly-silicon layer 17a is formed of doped poly-silicon, and may be formed of silicide, polycide, and a conductive layer of a high melting point metal.

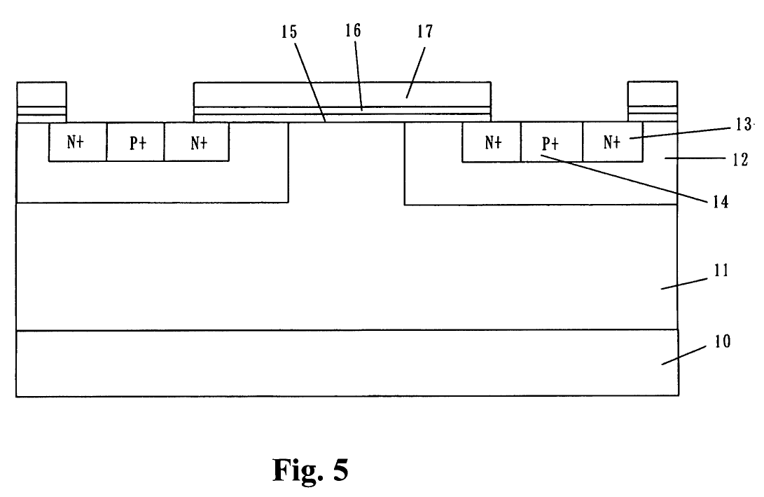

In the next step, as shown in FIG. 5, through a patterning process using photo-lithography technology, the poly-silicon layer 17a, the gate insulation film 16, and the Si layer 15 are coated with a resist, exposed, developed, and dry-etched, so that the poly-silicon layer 17a, the gate insulation film 16, and the Si layer 15 are removed in areas except a gate electrode forming area. After the patterning process, the resist is removed and cleaned, so that the gate electrode 17 is formed using the poly-silicon layer 17a.

In general, as opposed to a normal Si substrate, an impurity ion with a high concentration is difficult to diffuse in the SiC substrate 10. Accordingly, it is difficult to diffuse an impurity ion with a high concentration into a portion below the gate electrode 17 through a thermal process. To this end, in the step described above, the gate electrode 17 is formed such that a part of the gate electrode 17 is overlapped with a part of the source regions 13.

Further, in a case of a normal Si substrate, a gate electrode is formed first, and then an impurity ion with a high concentration is introduced with the gate electrode thus formed as a mask. In a case of the SiC substrate 10 in the embodiment, the order is reversed, and the gate electrode 17 is formed after an impurity ion with a high concentration is introduced.

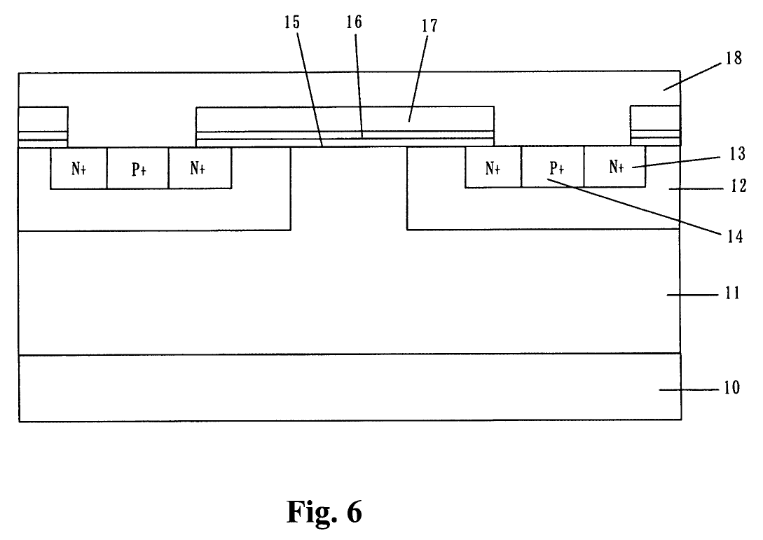

In the next step, as shown in FIG. 6, the interlayer insulation film 18 with a good insulation property is deposited over a whole surface including the gate electrode 17. In depositing the interlayer insulation film 18, there is used an LPCVD method such as LP-TEOS (Low Pressure Tetraethyl Orthosilicate), LP-SiN, HOT (High Temperature Oxide), LTO (Low Temperature Oxide), and the likes; a plasma CVD method; an ozone CVD method; an ALD (Atomic Layer Deposition) method; or the likes.

In the embodiment, the interlayer insulation film 18 is formed of an Si oxide film, an Si oxynitride film, an Si nitride film, an oxide film of titanium (Ti), tantalum (Ta), hafnium (Hf), zirconium (Zr), and the likes; or a silicate film.

In the next step, through the photo-lithography technology and the likes, the interlayer insulation film 18 is opened at the positions corresponding to the source regions 14, a part of the source regions 13, and the gate electrode 17. Then, a wiring portion is formed over a whole surface, and the wiring portion is patterned, so that the source electrodes 19 are formed and connected to the source regions 13 and 14, and the wiring portion 20 is formed and connected to the source electrodes 19 and the gate electrode 17. Afterward, the drain electrode 21 is formed on the backside surface of the SiC substrate 10, and is connected through ohmic connection, thereby obtaining the DiMOSFET of the vertical type shown in FIG. 1.

In the embodiment, the method of producing the semiconductor device includes the steps of forming the Si layer 15 on the SiC substrate 10, and forming the gate insulation film 16 formed of the oxide film or the oxynitride film through the oxidation or the oxynitridation process of the Si layer 15 such that a part of the Si layer 15 remains. Accordingly, it is possible to easily produce the DiMOSFET of the vertical type in the simple process.

As described above, in the embodiment, the gate insulation film 16 does not directly contact with the SiC substrate 10. As a result, it is possible to prevent carbon in the SiC substrate 10 from migrating into the gate insulation film 16. Therefore, it is possible to prevent an insulation voltage and reliability of the gate insulation film 16 from lowering, and to suppress an increase in a fixed charge amount in the gate insulation film 16.

Further, the interface between the gate insulation film 16 and the Si layer 15 prevents an interface trap density from increasing.

As described above, in the method of producing the semiconductor device in the embodiment, different from the conventional method, a part of the Si layer 15 remains, thereby preventing carbon in the SiC substrate 10 from migrating into the gate insulation film 16. In this case, if all of the Si layer 15 on the surface of the SiC substrate 10 is oxidized, the same effect may be achieved.

However, it is difficult to accurately control and oxidize the Si layer 15 on the SiC substrate 10 in terms of a manufacturing margin. Accordingly, in an actual case, it is necessary to oxide the Si layer 15 to an excess extent. When the Si layer 15 is oxidized to an excess extent, carbon in the SiC substrate 10 may diffuse into the gate insulation film 16, thereby generating fixed charges and interface traps. For the reason described above, in the method of producing the semiconductor device in the embodiment, a part of the Si layer 15 remains.

As described above, in the embodiment, there is the Si/SiC interface between the Si layer 15 and the SiC substrate 10. The Si/SiC interface may be regarded to be unstable in terms of interface traps, as opposed to a SiO₂/SiC interface in the conventional semiconductor device. Indeed, the Si/SiC interface may cause interface traps.

In the embodiment, 3C—SiC is grown epitaxially on Si, and it is possible to reduce dangling bonds at the Si/SiC interface. As known in the art, the dangling bonds refer to un-bonded atoms. Charges on the dangling bonds are unstable and become chemically active, thereby posing a significant influence on a property of a crystal surface. Accordingly, it is possible to prevent the interface traps from increasing.

That is, a main cause of the interface traps is the dangling bonds. Accordingly, when 3C-SiC is grown epitaxially completely, no interface traps are generated. Further, a band gap of Si is 1.12 eV, i.e., a half of a band gap of SiC. Accordingly, the number of the interface traps decreases with the band gap, thereby reducing an influence of the Si/SiC interface on a property of the transistor.

As described above, in the embodiment, a part of the Si layer 15 remains. In other words, a mere semiconductor element is added to a conventional transistor. Accordingly, as compared with a case in which a gate insulation film is directly formed on SiC in the conventional structure, a property of the transistor may be deteriorated.

In the embodiment, however, when a remaining part of the Si layer 15 has a large thickness (for example, larger than a few nm), the Si layer 15 functions as the channel. When a remaining part of the Si layer 15 has a small thickness (for example, smaller than a few nm), the channel is formed in the SiC substrate 10. In this case, fixed charges and interface traps are significantly reduced, thereby preventing a property of the transistor from being deteriorated.

When fixed charges and interface traps are generated, channel mobility decreases. Further, a threshold value of the transistor varies, and an S value increases. Accordingly, it is difficult to control deterioration of a property of the transistor or a variance. In the embodiment, an object is to significantly reduce fixed charges and interface traps. To this end, in the embodiment, a part of the Si layer 15 remains. Accordingly, it is possible to significantly reduce fixed charges and interface traps, thereby making it possible to control deterioration of a property of the transistor or a variance.

In the embodiment, when a part of the Si layer 15 remains, the remaining part of the Si layer 15 blocks carbon in the SiC substrate 10 from migrating into the gate insulation film 16, thereby reducing carbon in the gate insulation film 16. Accordingly, it is possible to significantly reduce fixed charges and interface traps, thereby making it possible to control deterioration of a property of the transistor or a variance.

When the remaining part of the Si layer 15 has a large thickness (for example, larger than a few nm), the Si layer 15 functions as the channel. When the remaining part of the Si layer 15 has a small thickness (for example, smaller than a few nm), the channel is formed in the SiC substrate 10.

### Second Embodiment

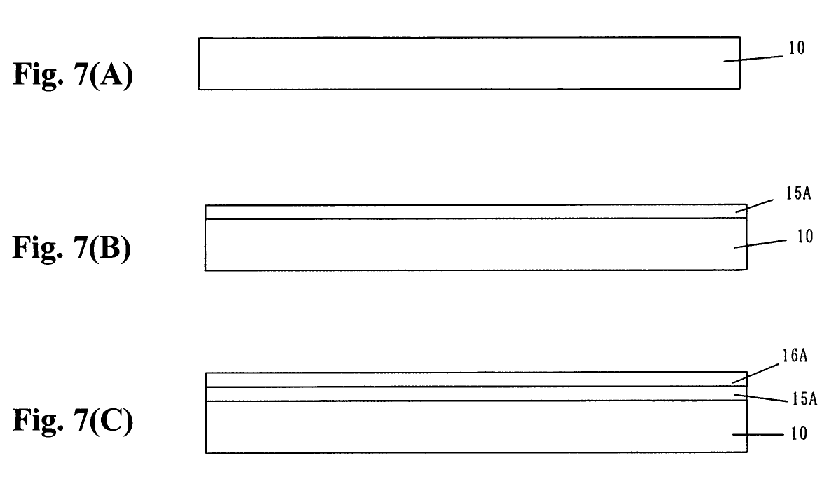

A second embodiment of the present invention will be explained next. FIGS. 7(A) to 7(C) are schematic sectional views showing a method of producing a semiconductor device according to the second embodiment of the present invention.

FIG. 7(A) corresponds to FIGS. 2(A) and 2(B). FIG. 7(B) corresponds to FIG. 3(A). FIG. 7(C) corresponds to FIG. 3(B).

In the second embodiment, similar to the first embodiment, the semiconductor device is a DiMOSFET of a vertical type. Instead of the laminated structure of the Si layer 15 and the gate insulation film 16 shown in FIG. 1, as shown in FIG. 7(C), the semiconductor device has a laminated structure of an Si layer 15A and a gate insulation film 16A.

A method of producing the semiconductor device will be explained next.

In the first step, as shown in FIG. 7(A) (corresponding to the steps shown in FIGS. 2(A) and 2(B)), the epitaxial layer 11, the well regions 12 of the P− type, the source regions 13 of the N+ type, and the source regions 14 of the P+ type are formed.

In the next step, as shown in FIG. 7(B) (corresponding to the step shown in FIG. 3(A)), the Si layer 15A having a thickness of, for example, 0.1 nm to 100 nm is formed on the SiC substrate 10. In forming the Si layer 15A, there is used a method such as a deposition method, a low pressure CVD (LPCVD) method, an atmospheric pressure CVD (APCVD) method, a plasma CVD method, sputtering, and the likes. The method is not limited thereto, and any one of the methods may be used.

In the next step, as shown in FIG. 7(C) (corresponding to the step shown in FIG. 3(B)), the gate insulation film 16A having a thickness of, for example, 1 nm to 100 nm is formed on the Si layer 15A. The gate insulation film 16A is formed through the LPCVD method such as LP-TEOS, LP-SiN, HTO, LTO, and the likes; the plasma CVD method; the ozone CVD method, the ALD method; and the likes. The gate insulation film 16A is formed a material such as an Si oxide film, an Si oxt-nitride film, an Si nitride film, and an oxide film of Al, Ti, Ta, Hf, Zr, and the likes. The method is not limited thereto, and any one of the methods and the insulation film material may be used.

In the next step, the process similar to the first embodiment shown in FIGS. 4 to 6 is performed, thereby obtaining the DiMOSFET of the vertical type.

As described above, in the embodiment, the Si layer 15A is formed on the SiC substrate 10, and the gate insulation film 16A is formed on the Si layer 15A to obtain the laminated structure. Accordingly, similar to the first embodiment, it is possible to easily produce the DiMOSFET of the vertical type in the simple process.

As described above, in the embodiment, the gate insulation film 16A does not directly contact with the SiC substrate 10. As a result, it is possible to prevent carbon in the SiC substrate 10 from migrating into the gate insulation film 16A. Therefore, it is possible to prevent an insulation voltage and reliability of the gate insulation film 16 from lowering due to carbon, and to suppress an increase in a charge amount in the gate insulation film 16A.

Further, the interface between the gate insulation film 16A and the Si layer 15 prevents an interface trap density from increasing.

In the first embodiment, the Si layer 15 is oxidized or oxynitrided to form the gate insulation film 16 on the surface of the Si layer 15. In the second embodiment, the gate insulation film 16A is formed on the Si layer 15A to obtain the laminated structure. Accordingly, it is possible to easily control thicknesses of the Si layer 15A and the gate insulation film 16A. Further, it is possible to use various materials for the gate insulation film 16A.

The present invention is not limited to the first and second embodiments, and various modifications are possible.

The present invention is not limited to the DiMOSFET, and is applicable to an SiC device using the gate insulation film 16 or 16A such as an MOSFET, an MOS capacitor, and the likes. The present invention is not limited to the DiMOSFET of the vertical type, and is applicable to an MOSFET of a lateral type having a source electrode, a gate electrode, and a drain electrode arranged on a same plane.

The method of producing the semiconductor device shown in FIGS. 2(A)-2(B) to 7(A)-7(C) are similar to a method of producing a semiconductor device using the SiC substrate 10 in general, and the order of the steps and the methods are not limited thereto.

The disclosure of Japanese Patent Application No. 2007-259700, filed on Oct. 3, 2007, is incorporated in the application by reference.

While the invention has been explained with reference to the specific embodiments of the invention, the explanation is illustrative and the invention is limited only by the appended claims.

What is claimed is:

1. A semiconductor device, comprising:
a silicon carbide substrate having a channel region formed on a surface thereof;
a silicon layer formed on the channel region;
a gate insulation film formed on the silicon layer; and
a gate electrode formed on the gate insulation film.

2. The semiconductor device according to claim 1, wherein said gate insulation film is formed of one of a silicon oxide film, a silicon oxynitride film, a silicon nitride film, an aluminum oxide film, a titanium oxide film, a tantalum oxide film, a hafnium oxide film, and a zirconium oxide film.

3. A method of producing a semiconductor device, comprising the steps of:
forming a silicon layer on a surface of a silicon carbide substrate;
oxidizing the silicon layer to form a gate insulation film formed of an oxide film so that a part of the silicon remains; and
forming a gate electrode on the gate insulation film.

4. A method of producing a semiconductor device, comprising the steps of:
forming a silicon layer on a surface of a silicon carbide substrate;
oxynitriding the silicon layer to form a gate insulation film formed of an oxynitride film so that a part of the silicon remains; and
forming a gate electrode on the gate insulation film.

5. The method of producing the semiconductor device according to claim 3, wherein, in the step of oxidizing the silicon layer to form the gate insulation film, the gate insulation film is formed of one of a silicon oxide film, a silicon oxynitride film, an aluminum oxide film, a titanium oxide film, a tantalum oxide film, a hafnium oxide film, and a zirconium oxide film.

6. The method of producing the semiconductor device according to claim 4, wherein, in the step of oxynitriding the silicon layer to form the gate insulation film, the gate insulation film is formed of one of a silicon oxynitride film and a silicon nitride film.
